(19) United States
(12) Patent Application Publication
(10) Pub. No.: US 2026/0213767 A1
(43) Pub. Date: Jul. 23, 2026

(54) ACT Startup Sequence

(71) Applicant: Infineon Technologies Americas Corp., El Segundo, CA (US)

(72) Inventors: Aleksei ZHEREBTSOV, Karlsruhe (DE); Seid Alireza RAZAVI MAJOMARD, Belmont, CA (US); Ragnar JONSSON, Aliso Viejo, CA (US)

(73) Assignee: Infineon Technologies Americas Corp., El Segundo, CA (US)

(21) Appl. No.: 19/455,573

(22) Filed: Jan. 21, 2026

Related U.S. Application Data
(60) Provisional application No. 63/747,782, filed on Jan. 21, 2025.

(51) Int. Cl. H03M 5/12; H04L 12/40

(52) U.S. Cl. CPC H03M 5/12; H04L 12/40

(57) ABSTRACT

A system and method of training communication paths between Ethernet devices. The method includes establishing, between an integrated circuit (IC) device and an Ethernet device, a first communication path to transmit a first signal at a first data rate to the Ethernet device and a second communication path to receive a second signal from the Ethernet device. The method includes executing a startup training sequence by transmitting a first set of training signals over the first communication path to optimize communication to the Ethernet device and receiving a second set of training signals over the second communication path to optimize communication from the Ethernet device. The method includes operating, upon completion of the startup training sequence, in a data mode to transmit the first signal via the first communication path and receive the second signal via the second communication path.

### CROSS-REFERENCE TO RELATED APPLICATIONS

This application claims the benefit of U.S. Provisional Application Ser. No. 63/747,782 entitled “ACT Startup Sequence,” filed Jan. 21, 2025, the disclosure of which is incorporated herein by reference in its entirety.

### TECHNICAL FIELD

The present disclosure relates generally to the field of wired Ethernet communications, and more particularly, to systems and methods of performing an Asymmetric Concurrent Transmission (ACT) startup sequence, including the generation and processing of associated training signals.

### BACKGROUND

Modern automotive and high-speed Ethernet deployments increasingly utilize asymmetric, multi-rate links (e.g., camera-to-switch connections) where upstream and downstream data rates differ. Existing IEEE 802.3ch startup procedures target symmetric, full-duplex links and do not sufficiently address timing acquisition, equalizer adaptation, and modulation readiness in asymmetric environments. Accordingly, there is a need for an ACT startup sequence that coordinates low-data-rate (LDR) and high-data-rate (HDR) training paths to enable robust PAM4 reception in the high-speed direction while maintaining reliable 100 Megabits per second (Mbps) operation in the low-speed direction.

### BRIEF DESCRIPTION OF THE DRAWINGS

The present disclosure is illustrated by way of example, and not by way of limitation, in the figures of the accompanying drawings in which like reference numerals refer to similar elements and in which:

FIG. 1 illustrates an example Ethernet Multi-Rate Networking (EMRN) system for processing Automotive Ethernet and High-Speed Ethernet signals, according to some embodiments;

FIG. 2 illustrates an example of a multi-mode Physical Coding Sublayer (PCS) configured to perform an ACT startup sequence, including the generation and processing of associated training signals, according to some embodiments;

FIG. 3 illustrates an example of an Ethernet device configured to perform an ACT startup sequence, including the generation and processing of associated training signals, according to some embodiments;

FIG. 4 illustrates an example structure of training sequences when an Ethernet Multi-Rate Integrated Circuit (EMRIC) device 102 is the Leader and an Ethernet device is the Follower, according to some embodiments;

FIG. 5 illustrates an example structure of training sequences when an Ethernet device 120 is the Leader and an EMRIC device is the Follower, according to some embodiments;

FIG. 6 illustrates an example automotive environment in which an EMRIC device may be deployed, in accordance with some embodiments; and

FIG. 7 illustrates a flow diagram of a procedure to perform an ACT startup sequence, according to some embodiments.

### DETAILED DESCRIPTION

The following description provides specific details such as examples of specific systems, components, methods, to support a clear understanding of various embodiments of the ACT startup sequence, including the generation and processing of associated training signals. It will be apparent to those skilled in the art, however, that at least some embodiments may be practiced without these specific details. In other instances, well-known components, elements, or methods are either not described in detail or are illustrated using simplified block diagrams to avoid obscuring the techniques described herein. Accordingly, the specific details presented below are merely exemplary, and particular implementations may differ while still falling within the scope of the present disclosure.

Modern automotive and high-speed Ethernet systems increasingly rely on asymmetric links (e.g., communication links), such as those between a camera module and a network switch, where the upstream and downstream data rates differ substantially. Conventional Ethernet Physical Layer (PHY) devices and startup procedures, including those defined in IEEE 802.3ch, are designed primarily for symmetric, full-duplex links and therefore do not provide adequate mechanisms for establishing timing alignment, equalizer adaptation, or modulation readiness in asymmetric environments. As a result, existing PHY architectures cannot reliably transition into high-speed PAM4 (Pulse Amplitude Modulation with 4 Levels) data transmission without a specialized training process that accounts for the unique characteristics of asymmetric camera-to-switch communication. Thus, there is a long-felt need for improved systems and methods that enable robust link initialization, training-signal exchange, and mode transitions to support Asymmetric Concurrent Transmission (ACT) operation.

Aspects of the present disclosure provide a mechanism for performing an ACT startup sequence, including the generation and processing of associated training signals. Specifically, an EMRIC device and an Ethernet device perform an ACT startup sequence to train each other for normal data flows. The ACT startup sequence is structured similarly to the IEEE 802.3ch startup procedure and begins with link-synchronization or auto-negotiation. During this sequence, one device (an EMRIC device or an Ethernet device) acts as the Leader (Master) and the other as the Follower (Slave). The Leader initiates transmission in a half-duplex mode using a first training signal, allowing the Follower to acquire timing and lock onto the received signal without interference from its own echo. After a defined interval, the Follower begins transmitting its own training signal. The devices then progress through PAM2 (Pulse Amplitude Modulation with 2 Levels) and PAM4 training stages in the high-data-rate direction to prepare the link for full-rate operation. Upon completion of both PAM training stages, the EMRIC device and the Ethernet device transition into a data mode, with link initialization and signal integrity improved as a result of the ACT startup training sequence.

An advantage of the described ACT startup sequence is that the use of half-duplex transmission during training provides favorable signal conditions for both devices. In conventional echo-canceled systems, half-duplex operation allows the Follower device to lock onto the received signal without interference from its own echo, and further enables the Leader device to train its echo-cancellation circuitry without disturbance from a simultaneously active remote transmitter. In the context of ACT operation, these benefits remain present but are less critical, as the echo levels encountered in ACT are substantially lower than those observed in full echo-canceled systems. Nonetheless, the half-duplex training structure contributes to robust timing acquisition, equalizer adaptation, and overall link stability during the startup sequence.

In an illustrative embodiment, an integrated circuit (IC) device including internal circuitry configured to establish, between the IC device and an Ethernet device, a first communication path to transmit a first signal at a first data rate to the Ethernet device and a second communication path to receive a second signal from the Ethernet device at a second data rate greater than the first data rate. The internal circuitry is further configured to execute a startup training sequence by transmitting a first set of training signals over the first communication path to optimize communication to the Ethernet device and receiving a second set of training signals over the second communication path to optimize communication from the Ethernet device. The internal circuitry is further configured to operate, upon completion of the startup training sequence, in a data mode to transmit the first signal via the first communication path and receive the second signal via the second communication path.

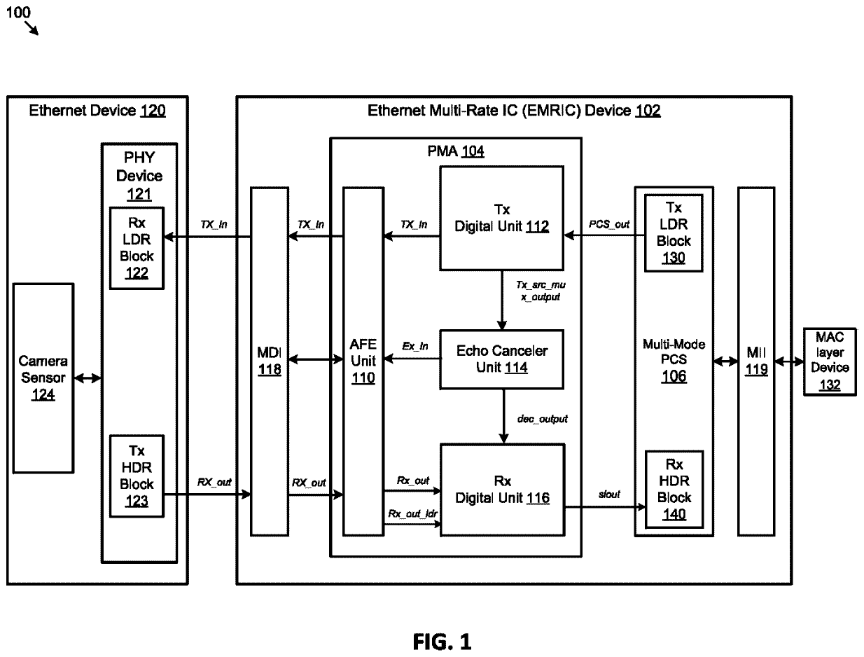

FIG. 1 illustrates an example Ethernet Multi-Rate Networking (EMRN) system for processing Automotive Ethernet and High-Speed Ethernet signals, according to some embodiments. The EMRN system 100 includes an Ethernet Multi-Rate IC (EMRIC) device 102 that is communicatively coupled between an Ethernet device 120 and a MAC layer device 132. In some embodiments, the EMRIC device 102 is referred to herein as a switch.

The Ethernet device 120 includes a Physical Layer (PHY) device 121 and a camera sensor 124. The camera sensor 124 captures image data and provides corresponding digital output signals to the PHY device 121 for transmission over the Ethernet link. The Ethernet device 120 includes an Rx Low Data Rate (LDR) block 122 configured to process signals (Tx_in) received from the EMRIC device 102 and a Tx High-Data Rate block 123 configured to send signals (Rx_out) to the EMRIC device 102.

Ethernet devices include, for example, automotive components such as cameras, radar units, LiDAR systems, ultrasonic sensors, and electronic control units (ECUs), as well as non-automotive devices such as industrial controllers, network switches, servers, and storage systems.

MAC layer devices include, for example, network interface controllers (NICs), Ethernet controllers integrated in system-on-chip (SoC) architectures, automotive gateway processors, and high-performance computing processors.

The EMRIC device 102 includes a Physical Medium Attachment (PMA) 104 that is communicatively coupled to the Ethernet device 120 (e.g., a camera module) via a media-dependent interface (MDI) 118. The EMRIC device 102 further includes a multi-mode PCS 106 that is communicatively coupled to the PMA 104. The multi-mode PCS 106 includes a Tx LDR block 130 that transmits a bitstream (PCS_out) to the PMA 104, and an Rx HDR block 140 that receives a bitstream (slout) from the PMA 104. The multi-mode PCS 106 is communicatively coupled to the MAC layer device 132 (i.e., an upper layer of the network stack) via a media-independent interface (MII) 119. Although not shown in FIG. 1, the PMA 104 interfaces with a Physical Medium Dependent (PMD) sublayer, which connects to the physical medium through the MDI 118.

The PMA 104 includes an analog front-end (AFE) unit 110 that is communicatively coupled to a Tx digital unit 112, an echo canceler unit 114, and an RX digital unit 116. The Tx digital unit 112 is communicatively coupled to the Tx LDR block 130 of the multi-mode PCS 106, and the Rx digital unit 116 is communicatively coupled to the Rx HDR block 140 of the multi-mode PCS 106. The AFE unit 110 provides analog signal conditioning for transmission and reception, while the Tx digital unit 112 and Rx digital unit 116 handle digital signal processing tasks associated with transmit and receive paths. The echo canceler unit 114 operates to mitigate interference caused by signal reflections during full-duplex communication.

The multi-mode PCS 106 is configured to encode and decode data (e.g., using 8B/10B encoding) and perform additional functions such as scrambling, insertion/removal of alignment markers, and auto-negotiation to establish link parameters between the EMRIC device 102 and the Ethernet device 120. The multi-mode PCS 106 acts as the highest sublayer of the physical layer, positioned between the PMA 104 and the MII 119.

Unlike conventional Physical Coding Sublayers that are typically designed to support a single Ethernet physical layer specification, the multi-mode PCS 106 is configured to process signals corresponding to multiple Ethernet PHY standards. For example, the multi-mode PCS 106 can process signals compliant with IEEE 802.3ch PHY and IEEE 802.3dm PHY. This multi-mode capability enables the EMRIC device 102 to interface with heterogeneous Ethernet environments without requiring separate PCSs for each PHY type.

In some embodiments, the multi-mode PCS 106 is further configured to support different variations of the IEEE 802.3dm PHY standard. For example, the multi-mode PCS 106 can process signals compliant with IEEE 802.3dm-ACT, which is an anticipated extension of IEEE 802.3dm that specifies additional capabilities for the Ethernet link. Although IEEE 802.3dm-ACT has not yet been formally adopted by the IEEE, the EMRIC device 102 is designed to accommodate such future variations to enable compatibility with evolving high-speed Ethernet environments without requiring separate PCS implementations.

In operation, data flows from the upper layers to the multi-mode PCS 106, which applies encoding and other processing before passing the data to the PMA 104. Within the PMA 104, the Tx digital unit 112 processes the outgoing data and forwards it to the AFE unit 110 for analog conversion and transmission over the physical medium via the PMD sublayer. Upon reception, the AFE unit 110 converts the incoming analog signal to digital form for the Rx digital unit 116, which forwards the data to the multi-mode PCS 106 for decoding and additional processing prior to delivery to the upper layers. The echo canceler unit 114 operates in parallel to reduce signal reflections and improve link quality.

To improve link initialization and signal integrity, the EMRIC device 102 and the Ethernet device 120 initially perform an ACT startup sequence to train the links between each device for normal data flows. These links include an LDR transmit link or path (carrying PCS_out and Tx_in) between the Tx LDR block 130 of the multi-mode PCS 106 and the Rx LDR block 122 of the PHY device 121; and an HDR receive link or path (carrying Rx_out, Rx_out_ldr, and slout) between the Tx HDR block 123 of the Ethernet device 120 and the Rx HDR Block 140 of the EMRIC device 102.

The ACT startup sequence is structured similarly to the IEEE 802.3ch startup procedure and begins with link-synchronization or auto-negotiation. During this sequence, one device (EMRIC device 102 or Ethernet device 120) assumes the role of Leader (Master) and the other assumes the role of Follower (Slave). The Leader initiates transmission in a half-duplex mode using a first training signal, allowing the Follower to acquire timing and lock onto the received signal without interference from its own echo. After a defined interval, the Follower begins transmitting its own training signal. The devices then progress through successive training stages, including a PAM2 (Pulse Amplitude Modulation with 2 Levels) training phase and a PAM4 (Pulse Amplitude Modulation with 4 Levels) training phase in the high-data-rate direction, to prepare the link for full-rate operation. Upon completion of the PAM4 training stage, the EMRIC device 102 and the Ethernet device 120 transition into data mode.

In some embodiments, the EMRIC device 102 is implemented on a single integrated circuit (IC), which refers to a monolithic semiconductor die containing multiple interconnected electronic components forming a functional unit. In other embodiments, the PMA 104 and the Media Dependent Interface (MDI) 118 are implemented on a first IC, while the multi-mode PCS 106 and the Media Independent Interface (MII) 119 are implemented on a second IC.

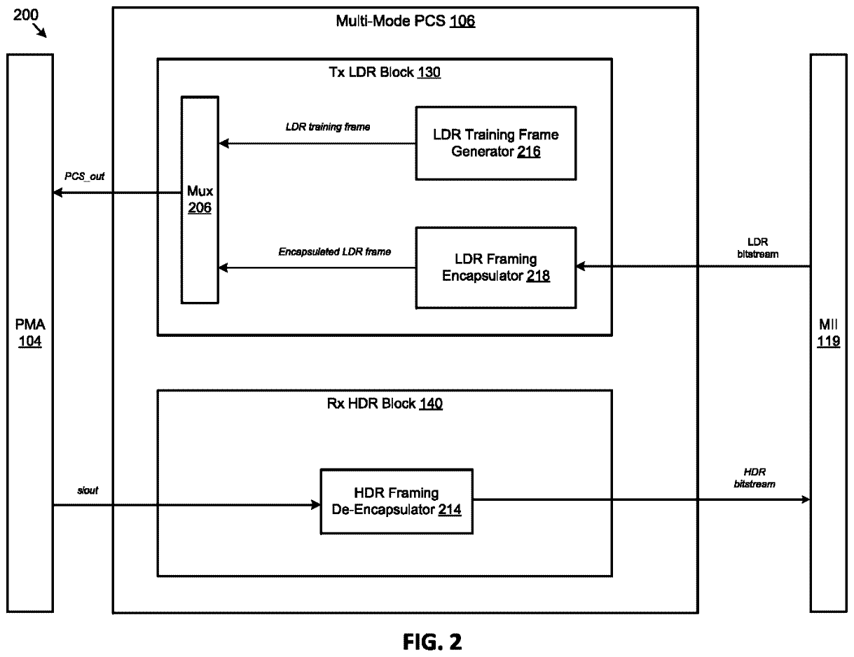

FIG. 2 illustrates an example of a multi-mode PCS configured to perform an Asymmetric Concurrent Transmission (ACT) startup sequence, including the generation and processing of corresponding training signals, according to some embodiments. The multi-mode PCS 106 includes both the Tx LDR block 130 and the Rx HDR block 140 from FIG. 1. The Tx LDR block 130 includes an LDR training frame generator 216, an LDR framing encapsulator 218, and a multiplexer (mux 206). The Rx HDR block 140 includes an HDR framing de-encapsulator 214.

Before entering data mode, the LDR training frame generator 216 generates an LDR training frame encoded using DME and transmits it to the mux 206, which forwards the LDR training frame to the Rx LDR block 122 of the Ethernet device 120 via the LDR transmit link between the Tx LDR block 130 of the EMRIC device 102 and the Rx LDR Block 122 of the Ethernet device 102. The Tx LDR block 130 then enters data mode. While in data mode, the LDR framing encapsulator 218 receives an LDR bitstream (e.g., data) from the MII 119, generates an encapsulated LDR frame from the LDR bitstream, and transmits the encapsulated LDR frame to the mux 206. The mux 206 then forwards the encapsulated LDR frame to the Rx LDR block 122 of the Ethernet device 120 via the PMA 104 and MDI 118.

Regarding the Rx HDR block 140, the HDR framing de-encapsulator 214 receives encapsulated HDR frames (slout corresponding to data or training frames) from the Tx HDR block 123 of the Ethernet device 120 via the PMA 104 and MDI 118. The HDR framing de-encapsulator 214 de-encapsulates the received encapsulated HDR frames to generate an HDR bitstream and forwards the HDR bitstream to the MAC layer device 132 via the MII 119.

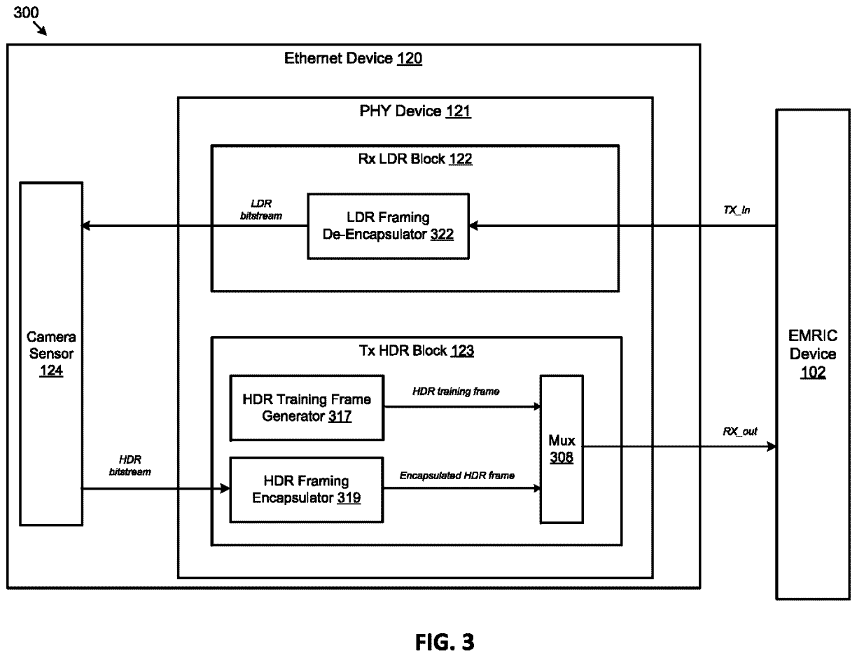

FIG. 3 illustrates an example of an Ethernet device configured to perform an ACT startup sequence, including the generation and processing of associated training signals, according to some embodiments. The Ethernet device 120 includes both the PHY device 121 and the camera sensor 124 from FIG. 1. The Tx HDR block 123 of the PHY device 121 includes an HDR training frame generator 317, an HDR framing encapsulator 319, and a multiplexer (mux 308). The Rx LDR block 122 of the PHY device 121 includes an LDR framing de-encapsulator 322, which is sometimes referred to herein as an interpolator.

Before entering data mode, the HDR training frame generator 317 performs its training based on PAM2 and then PAM4. Initially, the HDR training frame generator 317 generates an HDR training frame (sometimes referred to as PAM2 training frame) based on PAM2 and transmits it to the mux 308, which forwards the PAM2 training frame to the Rx HDR block 140 of the EMRIC device 102 via the MDI 118 and PMA 104. Then, the HDR training frame generator 317 generates a subsequent HDR training frame (sometimes referred to as PAM4 training frame) based on PAM4 and transmits it to the mux 308, which forwards the PAM4 training frame to the Rx HDR block 140 of the EMRIC device 102 via the MDI 118 and PMA 104. The Tx HDR block 123 then enters data mode.

While in data mode, the HDR framing encapsulator 319 receives an HDR bitstream (data) from the camera sensor 124, generates an encapsulated HDR frame from the HDR bitstream, and transmits the encapsulated HDR frame to the mux 308. The mux 308 then forwards the encapsulated HDR frame to the Rx HDR block 140 of the EMRIC device 102 via the MDI 118 and PMA 104.

Regarding the Rx LDR block 122, the LDR framing de-encapsulator 322 receives encapsulated LDR frames (Tx_in corresponding to data or training frames) from the Tx LDR block 130 of the EMRIC device 102. The LDR framing de-encapsulator 322 de-encapsulates the received encapsulated LDR frames to generate an LDR bitstream and forwards it to the camera sensor 124.

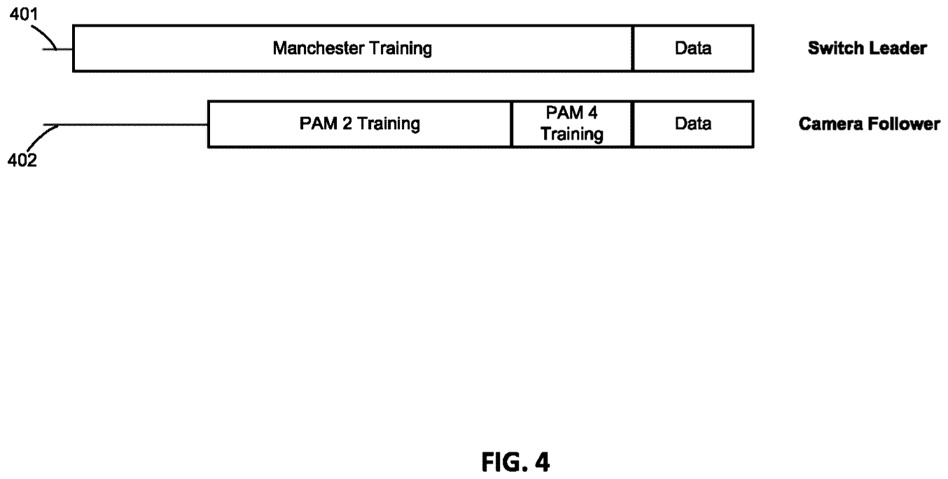

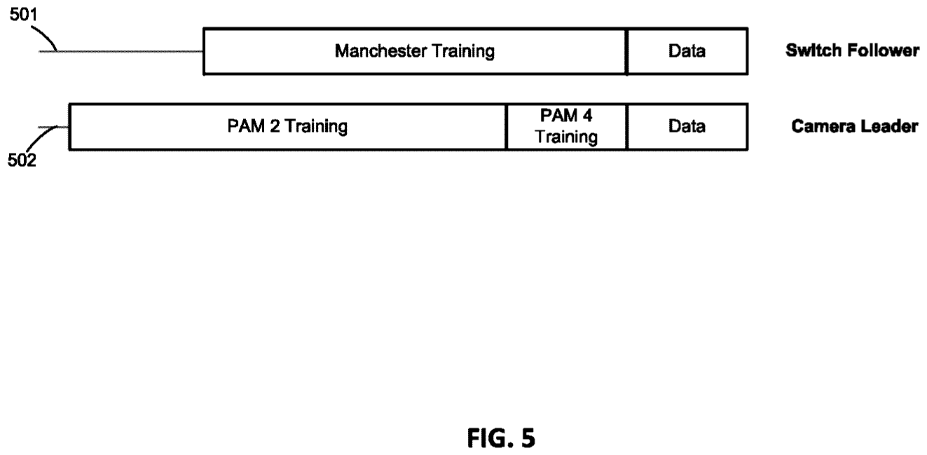

FIGS. 4-5 illustrate an example structure of training sequences used during the ACT setup procedure, according to some embodiments. Specifically, FIG. 4 illustrates an example structure of training sequences when an EMRIC device is the Leader and an Ethernet device is the Follower, according to some embodiments. Training sequence 401 is when a switch (e.g., EMRIC device 102) is the Leader and training sequence 402 is when a camera (e.g., Ethernet device 120) is the Follower. Conversely, FIG. 5 illustrates an example structure of training sequences when an Ethernet device is the Leader and an EMRIC device is the Follower, according to some embodiments. Training sequence 501 is when a camera (e.g., Ethernet device 120) is the Leader and training sequence 502 is when a switch (e.g., EMRIC device 102) is the Follower. Both diagrams depict the progression of training signals exchanged between devices while operating in training mode, including the transition between different modulation formats prior to entering normal data mode. In some embodiments, the Leader device may also be referred to as the Master and the Follower device as the Slave.

In accordance with the IEEE 802.3dm specification, the training sequence for high-speed operation begins with a PAM2-based training signal and subsequently transitions to a PAM4-based training signal before the devices (EMRIC device 102 and Ethernet device 120) enter data mode. This staged approach enables the receiving device to first acquire timing and perform initial equalizer adaptation using the lower-complexity PAM2 signal, followed by refinement of equalization and sampling parameters using the higher-order PAM4 signal.

For ACT operation, it is advantageous to employ a similar training-signal structure for the high-data-rate transmission path originating from the camera device. Using PAM2 followed by PAM4 during the training mode allows the receiving device to reliably prepare for full-rate PAM4 data transmission in the high-speed direction.

For the lower-rate 100 Mbps direction, the training sequence is performed using a DME signal. During this phase, the transmitting device generates and sends training frames encoded with DME, enabling the receiving device to acquire timing, establish link synchronization, and perform any necessary adaptation prior to entering normal data mode.

### Manchester Training

During the ACT startup sequence, the 100 Mbps DME training signal is used to support timing acquisition and sampling alignment between the EMRIC device and the Ethernet device. When the switch (EMRIC device 102) operates as the Leader, the primary purpose of the DME training signal is to allow the camera PHY within the Ethernet device 120 to lock onto the Leader's clock. Once the camera PHY has achieved clock lock, it is prepared to begin transmitting its own training signals as part of the ACT sequence.

Conversely, when the camera operates as the Leader, the primary purpose of the 100 Mbps DME training signal is to allow the camera PHY to establish the correct sampling phase at the receiving side of the EMRIC device 102. In this configuration, the camera PHY requires only a short interval of DME training to acquire the appropriate sampling phase before the devices proceed to subsequent stages of the training sequence.

Thus, depending on which device assumes the Leader role, the DME training signal enables either clock-locking or sampling-phase acquisition, ensuring that both devices are properly synchronized before transitioning to the higher-order PAM2 and PAM4 training stages.

### PAM2 Training

During the ACT startup sequence, the PAM2 training signal is used to support equalizer adaptation and timing alignment prior to transitioning to PAM4 training and normal data mode. When the camera operates as the Leader, the primary purpose of the PAM2 training signal is to allow the switch PHY within the EMRIC device 102 to train its equalizers and lock onto the Leader's clock. Once the switch PHY has completed equalizer adaptation and achieved clock lock, it is prepared to begin transmitting its own training signals as part of the ACT sequence.

Conversely, when the switch operates as the Leader, the primary purpose of the PAM2 training signal is to allow the camera PHY within the Ethernet device 120 to perform equalizer training. In this configuration, the PAM2 signal provides a stable, lower-complexity modulation format that enables the camera PHY to adapt its equalizers before the devices proceed to the subsequent PAM4 training stage.

In both role configurations, the PAM2 training signal provides the necessary conditions for equalizer convergence and timing stability, ensuring that the devices are properly conditioned for the higher-order PAM4 training signal and the eventual transition into normal data mode.

### PAM4 Training

During the ACT startup sequence, the PAM4 training signal is used to prepare the devices for a seamless transition into normal data mode. The PAM4 training stage enables the receiving PHY to finalize equalizer adaptation, sampling alignment, and decision-threshold calibration required for reliable PAM4 data reception.

When the camera PHY begins operating as the Leader and is preparing to transmit PAM4 signals, the switch PHY within the EMRIC device 102 must be fully conditioned to receive PAM4 modulation. Accordingly, the PAM4 training signal provides the switch PHY with the necessary information to complete its adaptation prior to the initiation of PAM4 data transmission.

To ensure proper coordination between devices, the PAM4 training stage includes a mechanism by which the receiving PHY can indicate that it is ready to accept PAM4 signals. This handshake allows the transmitting device to confirm that the receiving device has completed its PAM4-related adaptation before transitioning from training mode into normal data mode.

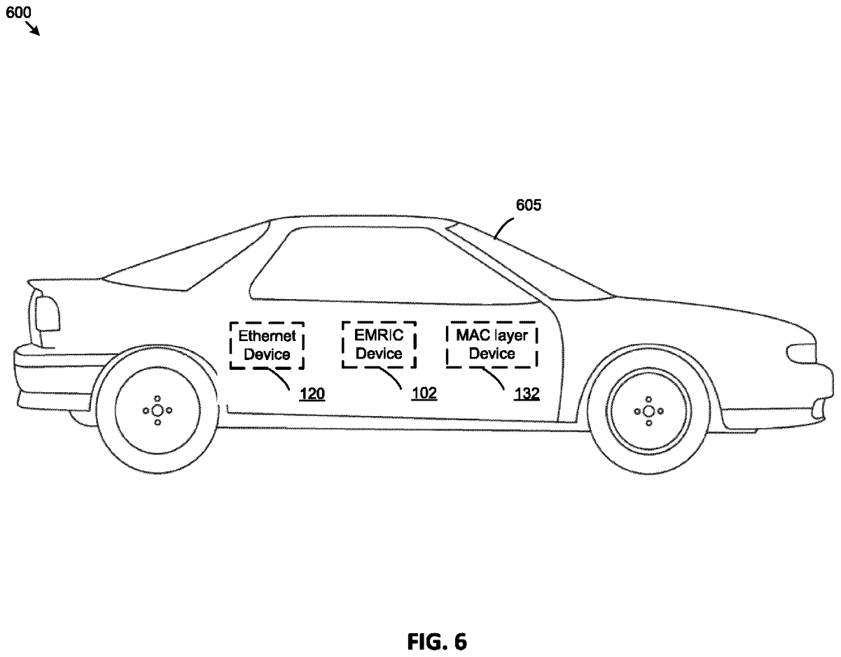

FIG. 6 illustrates an example automotive environment in which an EMRIC device may be deployed, in accordance with some embodiments. Environment 600 includes a car 605 that incorporates EMRIC device 102, which may correspond to any EMRIC device discussed herein. The EMRIC device 102 is electrically coupled to one or more Ethernet devices 120 and MAC layer devices 132. In some embodiments, the automotive environment may include multiple Ethernet-enabled components such as cameras, radar sensors, and LiDAR units connected to the EMRIC device via twisted-pair cabling.

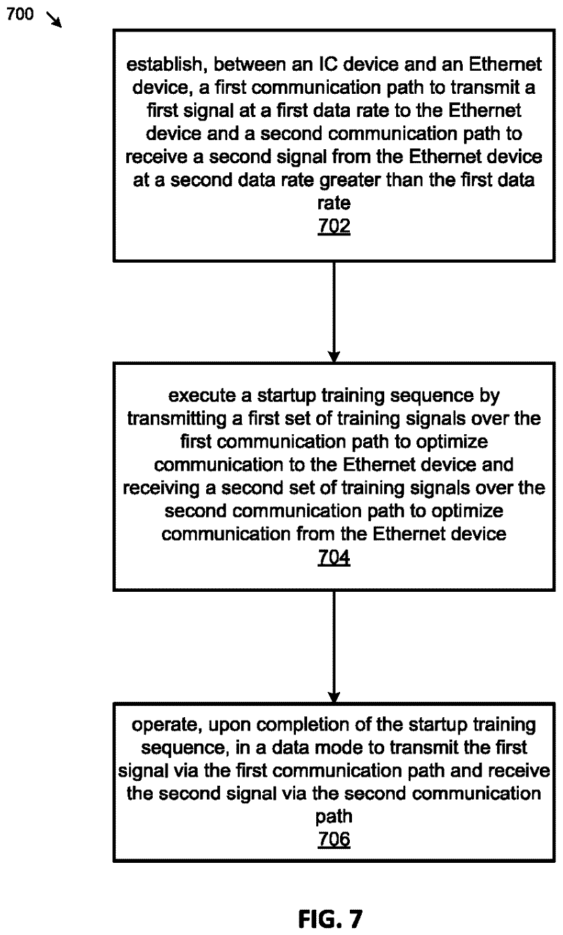

FIG. 7 illustrates a flow diagram of a procedure to perform an ACT startup sequence, according to some embodiments. The one or more operations of procedure 700 may be performed by the EMRIC device 102 in FIG. 1. The one or more operations of procedure 700 may be performed by the Ethernet device 120 in FIG. 1. The procedure 700 begins at operation 702, which includes establishing, between an IC device and an Ethernet device, a first communication path to transmit a first signal at a first data rate to the Ethernet device and a second communication path to receive a second signal from the Ethernet device at a second data rate greater than the first data rate.

Operation 704 includes executing a startup training sequence by transmitting a first set of training signals over the first communication path to optimize communication to the Ethernet device and receiving a second set of training signals over the second communication path to optimize communication from the Ethernet device.

Operation 706 includes operating, upon completion of the startup training sequence, in a data mode to transmit the first signal via the first communication path and receive the second signal via the second communication path.

The following examples illustrate embodiments of the EMRIC device 102 (sometimes referred to as a multi-rate integrated circuit (IC)) in FIG. 1.
Example 1 is a system including a multi-rate IC device comprising internal circuitry configured to establish, between the multi-rate IC device and an Ethernet device, a first communication path to transmit a first signal at a first data rate to the Ethernet device and a second communication path to receive a second signal from the Ethernet device at a second data rate greater than the first data rate; execute a startup training sequence by transmitting a first set of training signals over the first communication path to optimize communication to the Ethernet device and receiving a second set of training signals over the second communication path to optimize communication from the Ethernet device; and operate, upon completion of the startup training sequence, in a data mode to transmit the first signal via the first communication path and receive the second signal via the second communication path.
Example 2 is the system of Example 1 including the internal circuitry further configured to generate the first set of training signals using Differential Manchester Encoding.
Example 3 is the system of Example 2 including wherein the first set of training signals causes the Ethernet device to lock onto a master clock of the multi-rate IC device when the multi-rate IC device operates in a master mode and the Ethernet device operates in a slave mode.
Example 4 is the system of Example 2 including wherein the first set of training signals causes the Ethernet device to acquire a sampling phase of the multi-rate IC device when the multi-rate IC device operates in a slave mode and the Ethernet device operates in a master mode.
Example 5 is the system of Example 2 including the internal circuitry further configured to receive a pulse amplitude modulation with two levels (PAM2) training signal over the second communication path.
Example 6 is the system of Example 5 including wherein to receive the second set of training signals over the second communication path, the internal circuitry is further configured to lock, based on the PAM2 training signal, onto a master clock of the Ethernet device when the Ethernet device operates in a master mode and the multi-rate IC device operates in a slave mode.
Example 7 is the system of Example 6 including the internal circuitry further configured to train one or more equalizers of the multi-rate IC device responsive to locking onto the master clock of the Ethernet device.
Example 8 is the system of Example 5 including wherein the PAM2 training signal is to be used by the Ethernet device when the multi-rate IC device operates in a master mode and the Ethernet device operates in a slave mode.
Example 9 is the system of Example 5 including the internal circuitry further configured to receive, after receiving the PAM2 training signal, a pulse amplitude modulation with four levels (PAM4) training signal over the second communication path.
Example 10 is the system of Example 1 including wherein the first signal corresponds to a first transmission protocol comprising Institute of Electrical and Electronics Engineers (IEEE) 802.3.

Example 11 is a method including establishing, between a multi-rate IC device and an Ethernet device, a first communication path to transmit a first signal at a first data rate to the Ethernet device and a second communication path to receive a second signal from the Ethernet device at a second data rate greater than the first data rate; executing a startup training sequence by transmitting a first set of training signals over the first communication path to optimize communication to the Ethernet device and receiving a second set of training signals over the second communication path to optimize communication from the Ethernet device; and operating, upon completion of the startup training sequence, in a data mode to transmit the first signal via the first communication path and receive the second signal via the second communication path.
Example 12 is the method of Example 11 including generating the first set of training signals using Differential Manchester Encoding.
Example 13 is the method of Example 12 including wherein the first set of training signals causes the Ethernet device to lock onto a master clock of the multi-rate IC device when the multi-rate IC device operates in a master mode and the Ethernet device operates in a slave mode.
Example 14 is the method of Example 12 including wherein the first set of training signals causes the Ethernet device to acquire a sampling phase of the multi-rate IC device when the multi-rate IC device operates in a slave mode and the Ethernet device operates in a master mode.
Example 15 is the method of Example 12 including receiving a pulse amplitude modulation with two levels (PAM2) training signal over the second communication path.
Example 16 is the method of Example 15 including wherein receiving the second set of training signals over the second communication path further comprises locking, based on the PAM2 training signal, onto a master clock of the Ethernet device when the Ethernet device operates in a master mode and the multi-rate IC device operates in a slave mode.
Example 17 is the method of Example 16 including training one or more equalizers of the multi-rate IC device responsive to locking onto the master clock of the Ethernet device.
Example 18 is the method of Example 15 including wherein the PAM2 training signal is to be used by the Ethernet device when the multi-rate IC device operates in a master mode and the Ethernet device operates in a slave mode.
Example 19 is the method of Example 15 including receiving, after receiving the PAM2 training signal, a pulse amplitude modulation with four levels (PAM4) training signal over the second communication path.
Example 20 is a system including an Ethernet device comprising internal circuitry configured to establish, between the Ethernet device and an IC device, a first communication path to receive a first signal at a first data rate from the IC device and a second communication path to transmit a second signal to the IC device at a second data rate greater than the first data rate; execute a startup training sequence by receiving a first set of training signals over the first communication path to optimize communication from the PCS and transmitting a second set of training signals over the second communication path to optimize communication to the PCS; and operate, upon completion of the startup training sequence, in a data mode to receive the first signal via the first communication path and transmit the second signal via the second communication path.

In the above description, some portions of the detailed description are presented in terms of algorithms and symbolic representations of operations on analog signals and/or digital signals or data bits within a non-transitory storage medium. These algorithmic descriptions and representations are the means used by those skilled in the data processing arts to most effectively convey the substance of their work to others skilled in the art. An algorithm is here and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared and otherwise manipulated. It has proven convenient at times, principally for reasons of common usage, to refer to these signals as bits, values, elements, symbols, characters, terms, numbers, or the like.

Reference in the description to “an embodiment,” “one embodiment,” “an example embodiment,” “some embodiments,” and “various embodiments” means that a particular feature, structure, step, operation, or characteristic described in connection with the embodiment(s) is included in at least one embodiment of the disclosure. Further, the appearances of the phrases “an embodiment,” “one embodiment,” “an example embodiment,” “some embodiments,” and “various embodiments” in various places in the description do not necessarily all refer to the same embodiment(s).

The description includes references to the accompanying drawings, which form a part of the detailed description. The drawings show illustrations in accordance with exemplary embodiments. These embodiments, which may also be referred to herein as “examples,” are described in enough detail to enable those skilled in the art to practice the embodiments of the claimed subject matter described herein. The embodiments may be combined, other embodiments may be utilized, or structural, logical, and electrical changes may be made without departing from the scope and spirit of the claimed subject matter. The embodiments described herein are not intended to limit the scope of the subject matter but rather to enable one skilled in the art to practice, make, and/or use the subject matter.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “receiving,” “establishing,” “executing,” “operating,” or the like, refer to the actions and processes of an integrated circuit (IC) controller, or similar electronic device, that manipulates and transforms data represented as physical (e.g., electronic) quantities within the controller's registers and memories into other data similarly represented as physical quantities within the controller memories or registers or other such information non-transitory storage medium.

The words “example” or “exemplary” are used herein to mean serving as an example, instance, or illustration. Any aspect or design described herein as “example’ or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such.

Embodiments described herein may also relate to an apparatus (e.g., such as an EMRIC device 102) for performing the operations herein. This apparatus may be specially constructed for the required purposes, or it may include firmware or hardware logic selectively activated or reconfigured by the apparatus. Such firmware may be stored in a non-transitory computer-readable storage medium, such as, but not limited to, read-only memories (ROMs), random access memories (RAMs), EPROMs, EEPROMs, flash memory, or any type of media suitable for storing electronic instructions. The term “computer-readable storage medium” should be taken to include a single medium or multiple media that store one or more sets of instructions. The term “computer-readable medium” shall also be taken to include any medium that is capable of storing, encoding, or carrying a set of instructions for execution by the machine and that causes the machine to perform any one or more of the methodologies of the present embodiments. The term “computer-readable storage medium” shall accordingly be taken to include, but not be limited to, solid-state memories, optical media, magnetic media, any medium that is capable of storing a set of instructions for execution by the machine and that causes the machine to perform any one or more of the methodologies of the present embodiments.

The above description sets forth numerous specific details such as examples of specific systems, components, methods, and so forth, to provide a good understanding of several embodiments of the present disclosure. It is to be understood that the above description is intended to be illustrative and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. An integrated circuit (IC) device comprising internal circuitry configured to:
establish, between the IC device and an Ethernet device, a first communication path to transmit a first signal at a first data rate to the Ethernet device and a second communication path to receive a second signal from the Ethernet device at a second data rate greater than the first data rate;
execute a startup training sequence by transmitting a first set of training signals over the first communication path to optimize communication to the Ethernet device and receiving a second set of training signals over the second communication path to optimize communication from the Ethernet device; and
operate, upon completion of the startup training sequence, in a data mode to transmit the first signal via the first communication path and receive the second signal via the second communication path.

2. The IC device of claim 1, wherein the internal circuitry is further configured to:
generate the first set of training signals using Differential Manchester Encoding.

3. The IC device of claim 2, wherein the first set of training signals causes the Ethernet device to lock onto a master clock of the IC device when the IC device operates in a master mode and the Ethernet device operates in a slave mode.

4. The IC device of claim 2, wherein the first set of training signals causes the Ethernet device to acquire a sampling phase of the IC device when the IC device operates in a slave mode and the Ethernet device operates in a master mode.

5. The IC device of claim 2, wherein the internal circuitry is further configured to:
receive a pulse amplitude modulation with two levels (PAM2) training signal over the second communication path.

6. The IC device of claim 5, wherein to receive the second set of training signals over the second communication path, the internal circuitry is further configured to:
lock, based on the PAM2 training signal, onto a master clock of the Ethernet device when the Ethernet device operates in a master mode and the IC device operates in a slave mode.

7. The IC device of claim 6, wherein the internal circuitry is further configured to:
train one or more equalizers of the IC device responsive to locking onto the master clock of the Ethernet device.

8. The IC device of claim 5, wherein the PAM2 training signal is to be used by the Ethernet device when the IC device operates in a master mode and the Ethernet device operates in a slave mode.

9. The IC device of claim 5, wherein the internal circuitry is further configured to:
receive, after receiving the PAM2 training signal, a pulse amplitude modulation with four levels (PAM4) training signal over the second communication path.

10. The IC device of claim 1, wherein the first signal corresponds to a first transmission protocol comprising Institute of Electrical and Electronics Engineers (IEEE) 802.3.

11. A method comprising:
establishing, between an integrated circuit (IC) device and an Ethernet device, a first communication path to transmit a first signal at a first data rate to the Ethernet device and a second communication path to receive a second signal from the Ethernet device at a second data rate greater than the first data rate;
executing a startup training sequence by transmitting a first set of training signals over the first communication path to optimize communication to the Ethernet device and receiving a second set of training signals over the second communication path to optimize communication from the Ethernet device; and
operating, upon completion of the startup training sequence, in a data mode to transmit the first signal via the first communication path and receive the second signal via the second communication path.

12. The method of claim 11, further comprising:
generating the first set of training signals using Differential Manchester Encoding.

13. The method of claim 12, wherein the first set of training signals causes the Ethernet device to lock onto a master clock of the IC device when the IC device operates in a master mode and the Ethernet device operates in a slave mode.

14. The method of claim 12, wherein the first set of training signals causes the Ethernet device to acquire a sampling phase of the IC device when the IC device operates in a slave mode and the Ethernet device operates in a master mode.

15. The method of claim 12, further comprising:
receiving a pulse amplitude modulation with two levels (PAM2) training signal over the second communication path.

16. The method of claim 15, wherein receiving the second set of training signals over the second communication path further comprises:
locking, based on the PAM2 training signal, onto a master clock of the Ethernet device when the Ethernet device operates in a master mode and the IC device operates in a slave mode.

17. The method of claim 16, further comprising:
training one or more equalizers of the IC device responsive to locking onto the master clock of the Ethernet device.

18. The method of claim 15, wherein the PAM2 training signal is to be used by the Ethernet device when the IC device operates in a master mode and the Ethernet device operates in a slave mode.

19. The method of claim 15, further comprising:
receiving, after receiving the PAM2 training signal, a pulse amplitude modulation with four levels (PAM4) training signal over the second communication path.

20. An Ethernet device comprising internal circuitry configured to:
establish, between the Ethernet device and an integrated circuit (IC) device, a first communication path to receive a first signal at a first data rate from the IC device and a second communication path to transmit a second signal to the IC device at a second data rate greater than the first data rate;
execute a startup training sequence by receiving a first set of training signals over the first communication path to optimize communication from the IC device and transmitting a second set of training signals over the second communication path to optimize communication to the IC device; and
operate, upon completion of the startup training sequence, in a data mode to receive the first signal via the first communication path and transmit the second signal via the second communication path.
